(19) United States
(12) Patent Application Publication
(10) Pub. No.: US 2022/0302013 A1
(43) Pub. Date: Sep. 22, 2022

(54) SEMICONDUCTOR DEVICE PACKAGES AND METHODS OF MANUFACTURING THE SAME

(71) Applicant: Advanced Semiconductor Engineering Korea, Inc., Paju-Si (KR)

(72) Inventors: Youngsik PYUN, Paju-Si (KR); Kyuhwan SUL, Paju-Si (KR); Sunghee YOON, Paju-Si (KR)

(73) Assignee: Advanced Semiconductor Engineering Korea, Inc., Paju-Si (KR)

(21) Appl. No.: 17/207,307

(22) Filed: Mar. 19, 2021

(51) Int. Cl. H01L 23/498; H01L 21/48; H01L 23/31; H01L 21/56

(52) U.S. Cl. CPC H01L 23/49861; H01L 21/4821; H01L 23/49838; H01L 23/3185; H01L 21/56

(57) ABSTRACT

The present disclosure provides a semiconductor device package and a method of manufacturing the same. The semiconductor device package includes an encapsulant and a plurality of leads. The encapsulant has a first upper surface, a second upper surface, a first lateral surface and a second lateral surface. The first lateral surface extends between the first upper surface and the second upper surface, and the second upper surface extends between the first lateral surface and the second lateral surface. The leads are embedded in the encapsulant. One of the plurality of leads has a first surface exposed from the first upper surface of the encapsulant, a second surface exposed from the second upper surface of the encapsulant, a third surface extending between the first surface and the second surface, and a fourth surface extending from the third surface of the lead toward the first lateral surface of the encapsulant.

### BACKGROUND

### 1. Field of the Disclosure

The present disclosure relates to semiconductor device packages and methods of manufacturing the same.

### 2. Description of Related Art

Wettable flank can be used to improve the soldering performance of Quad Flat No-Lead (QFN), and to reduce inspection costs through optical inspection after soldering. Wettable flank ecan also improve the soldering quality of QFN, which can meet the criterion of soldering quality by visual observation.

However, existing wettable flank QFN (WF-QFN) has a structural weakness with respect to burr defects resulting from the cutting operations for the wettable flanks. Because of the ductile property of lead in the QFN, a portion of lead may be gradually lengthened during cutting operations and become a burr defect, which may cause a short defect between the leads, and make it difficult to achieve mass production.

### SUMMARY

According to some embodiments of the present disclosure, a semiconductor device package includes an encapsulant and a plurality of leads. The encapsulant has a first upper surface, a second upper surface, a first lateral surface and a second lateral surface. The first lateral surface extends between the first upper surface and the second upper surface, and the second upper surface extends between the first lateral surface and the second lateral surface. The leads are embedded in the encapsulant. At least one of the plurality of leads has a first surface exposed from the first upper surface of the encapsulant, a second surface exposed from the second upper surface of the encapsulant, a third surface extending between the first surface and the second surface, and a fourth surface extending from the third surface of the lead toward the first lateral surface of the encapsulant.

According to some embodiments of the present disclosure, a semiconductor device package includes an encapsulant and a plurality of leads. The encapsulant has a first upper surface, a second upper surface and a first lateral surface extending between the first upper surface and the second upper surface. The leads are embedded in the encapsulant. At least one of the plurality of leads has a protruding portion protruding from the second upper surface of the encapsulant, the first lateral surface of the encapsulant or both.

According to some embodiments of the present disclosure, a method of manufacturing a semiconductor device package includes: providing a package structure comprising two or more semiconductor device package units and an encapsulant covering a semiconductor device of each of the semiconductor device package units, wherein each of the semiconductor device package units comprises a plurality of leads disposed around a peripheral edge of the semiconductor device package unit and exposed from an upper surface of the package structure; (b) performing an energy-beam ablation operation to half-cut the package structure from the upper surface of the package structure to form a recess along the peripheral edge of the semiconductor device package units, wherein a lateral surface of the leads is exposed from the recess; and (c) performing a singulation operation to form an opening from the recess, wherein a width of the recess is greater than a width of the opening.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 illustrates a three-dimensional view of a semiconductor device package according to some embodiments of the present disclosure.

FIG. 2A illustrates a three-dimensional view of a semiconductor device package according to some embodiments of the present disclosure.

FIG. 2B illustrates a partial side view of the semiconductor device package of FIG. 2A.

FIG. 3A illustrates a three-dimensional view of a semiconductor device package according to some embodiments of the present disclosure.

FIG. 3B illustrates a partial side view of the semiconductor device package of FIG. 3A.

FIG. 4 illustrates a three-dimensional view of a semiconductor device package according to some embodiments of the present disclosure.

FIG. 5 illustrates a three-dimensional view of a semiconductor device package according to some embodiments of the present disclosure.

FIG. 6 illustrates a scanning electron microscopic image of a semiconductor device package according to some embodiments of the present disclosure.

FIG. 7A, FIG. 7B, FIG. 7C, FIG. 8A, FIG. 8B, FIG. 8C, FIG. 9A, FIG. 9B and FIG. 9C illustrate various stages of a method for manufacturing a semiconductor device package in accordance with some embodiments of the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides many different embodiments, or examples, for implementing different features of the provided subject matter. Specific examples of components and arrangements are described below. These are, of course, merely examples and are not intended to be limiting. In the present disclosure, reference to the formation or disposal of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

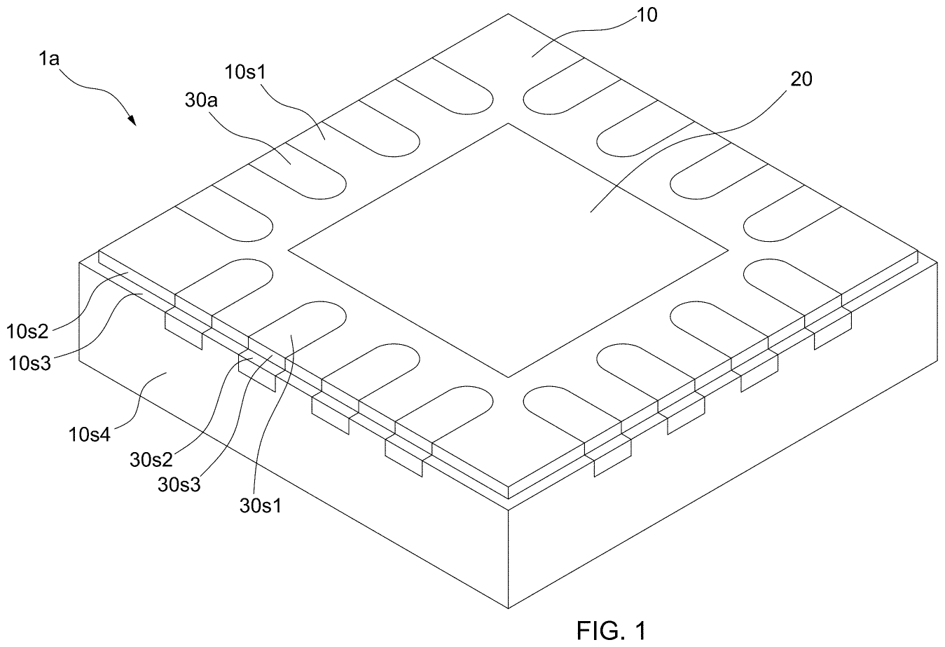

FIG. 1 illustrates a three-dimensional view of a semiconductor device package 1a according to some embodiments of the present disclosure.

In some embodiments, the semiconductor device package 1a may include an encapsulant 10, a die paddle 20 and a plurality of leads 30a.

The encapsulant 10 may include insulation or dielectric material. The encapsulant 10 may be made of molding material that may include, for example, a Novolac-based resin, an epoxy-based resin, a silicone-based resin, or other suitable encapsulant. Suitable fillers may also be included, such as powdered SiO₂. In some embodiments, the encapsulant 10 may have a step-like structure. For example, the encapsulant 10 may have an upper surface 10s1, a lateral surface 10s2, an upper surface 10s3 and a lateral surface 10s4. The upper surface 10s1 and the upper surface 10s3 may be substantially parallel to each other. The upper surface 10s1 and the upper surface 10s3 may be located at different elevations or heights. For example, the height of the upper surface 10s1 may be higher than that of the upper surface 10s3. The lateral surface 10s2 may extend in a direction different from that of the upper surface 10s1. For example, the lateral surface 10s2 may be substantially perpendicular to the upper surface 10s1 or the upper surface 10s3. The lateral surface 10s2 may extend between the upper surface 10s1 and the upper surface 10s3. The lateral surface 10s4 may be substantially parallel to the lateral surface 10s2. The upper surface 10s3 may extend between the lateral surface 10s2 and the lateral surface 10s4. In some embodiments, the upper surface 10s1 and the lateral surface 10s2 may define a first step. In some embodiments, the upper surface 10s3 and the lateral surface 10s4 may define a second step.

The die paddle 20 may be embedded in the encapsulant 10. The die paddle 20 may be exposed from the upper surface 10s1 of the encapsulant. The die paddle 20 may be disposed in a relatively central region of the encapsulant 10. The die paddle 20 may be separated from the leads 30a. The die paddle 20 and the lead 30a can be made of copper, copper alloy or another suitable metal or metal alloy. In some embodiments, the die paddle 20 and the lead 30a may include one or a combination of the following: iron, nickel, iron alloy, nickel alloy or any other suitable metal or metal alloy. The die paddle 20 may be configured to, for example, serve as a carrier on which electronic component(s) (not shown) are disposed.

The leads 30a may be embedded in the encapsulant 10. The lead 30a may be exposed from the upper surface 10s1, the lateral surface 10s2, the upper surface 10s3 and the lateral surface 10s4 of the encapsulant 10. The plurality of leads 30a may be disposed in a relatively peripheral region of the encapsulant 10 and surround the die paddle 20. Each of the leads 30a may have an upper surface 30s1, an upper surface 30s2 and a lateral surface 30s3. The upper surface 30s1 of the lead 30a may be exposed from the upper surface 10s1 of the encapsulant 10. The upper surface 30s1 of the lead 30a may be substantially coplanar with the upper surface 10s1 of the encapsulant 10. The upper surface 30s2 of the lead 30a may be exposed from the upper surface 10s3 of the encapsulant 10. The upper surface 30s2 of the lead 30a may be substantially coplanar with the upper surface 10s3 of the encapsulant 10. The upper surface 10s3 of the encapsulant 10 may be at substantially the same elevation as the upper surface 30s2 of the lead 30. The lateral surface 30s3 of the lead 30a may be exposed from the lateral surface 10s2 of the encapsulant 10. The lateral surface 30s3 of the lead 30a may be substantially coplanar with the lateral surface 10s2 of the encapsulant 10. In some embodiments, the lead 30a may have a step-like structure corresponding to that of the encapsulant 10 and the lateral surface 30s3 and the upper surface 30s1 may define a first step. In some embodiments, the semiconductor package structure la may be a Quad Flat No-Lead (QFN) package. The lead 30a may serve as a solder wettable flank, which may be used for inspection to ensure the joint quality between the semiconductor device package (such as the semiconductor package structure la and other electronic components (such as a motherboard, not shown).

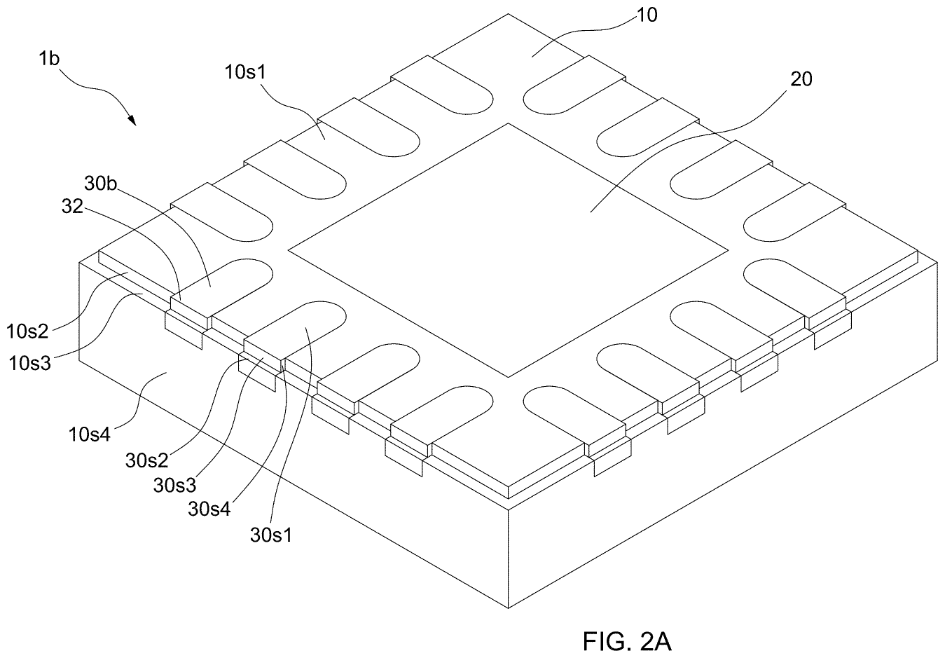

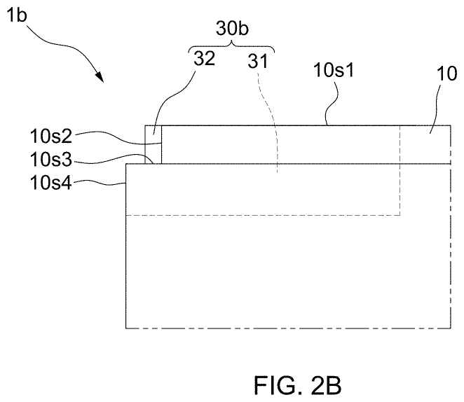

FIG. 2A illustrates a three-dimensional view of a semiconductor device package 1b according to some embodiments of the present disclosure. The semiconductor device package 1b of FIG. 2A has a similar structure to that of the semiconductor device package 1a of FIG. 1, except for leads 30b of the semiconductor device package 1b.

In some embodiments, the lead 30b may have a protruding portion 32 protruding from either the upper surface 10s3, the lateral surface 10s2, or both, of the encapsulant 10. The term “protruding portion” discussed in this disclosure may mean that there is a distance greater than about 10 μm, such as 20 μm, 30 μm, 40 μm, 50 μm, 60 μm, 70 μm, 80 μm, 90 μm , 100 μm, 110 μm or 120 μm between the lateral surface 30s3 of the lead 30b and the surface (e.g., 10s2, 10s3) of the encapsulant 10 from which the lead 30 is protruding. In some embodiments, the lead 30b may have a lateral surface 30s4. The lateral surface 30s4 may extend in a direction different from that of the lateral surface 30s3. The lateral surface 30s4 may extend in a direction different from that of the upper surface 30s1. The lateral surface 30s4 may extend between the upper surface 30s2 and the upper surface 30s1 of the lead 30b. The lateral surface 30s4 may extend from the lateral surface 30s3 of the lead 30b toward the lateral surface 10s2 of the encapsulant 10. In some embodiments, the lateral surface 30s4 of the lead 30b may be in contact with the upper surface 10s3 of the encapsulant 10. In some embodiments, the lateral surface 30s4 of the lead 30b may be in contact with the lateral surface 10s2 of the encapsulant 10. In this embodiment, the lead 30b may have at least three lateral sides (such as one lateral surface 30s3 and two lateral surfaces 30s4) between the upper surface 30s1 and the upper surface 30s2. In some embodiments, a distance from the lateral surface 10s4 of the encapsulant 10 to the lateral surface 10s2 of the encapsulant 10 is greater than a distance from the lateral surface 30s3 of the lead 30 to the lateral surface 10s2 of the encapsulant 10.

FIG. 2B illustrates a partial side view of the semiconductor device package 1b of FIG. 2A. In some embodiments, the lead 30b may have an embedded portion 31. The dotted line is used to present the profile of the embedded portion 31 in this cross-section view. As shown in FIG. 2B, the embedded portion 31 of the lead 30b may have an L-shape. However, the profile of the embedded portion 31 is not intended to be limited. The embedded portion 31 of the lead 30b may be embedded in the encapsulant 10. The protruding portion 32 may be extend from the embedded portion 31. As shown in FIG. 2B, the protruding portion 32 may protrude from the upper surface 10s3, the lateral surface 10s2, or both, of the encapsulant 10. In some embodiments, the protruding portion 32 of the lead 30b may be spaced apart from the lateral surface 10s4 of the encapsulant 10. In some embodiments, the protruding portion 32 of the lead 30b is recessed from the lateral surface 10s4 of the encapsulant 10. In some other embodiments, the protruding portion 32 of the lead 30b may extend to the lateral surface 10s4 of the encapsulant 10. In some embodiments, the height of the protruding portion 32 of the lead 30b may be substantially the same as a distance from the upper surface 10s1 and the upper surface 10s3 of the encapsulant 10. As compared to the embodiments illustrated in FIG. 1, the protruding portion 32 may provide a greater area for jointing a conductive layer, such as a solder, thereby increasing the rigidity of the semiconductor device package 1b. Further, the formation of the protruding portion 32 may assist in inspecting solder joints more easily by automated optical inspection (AOI).

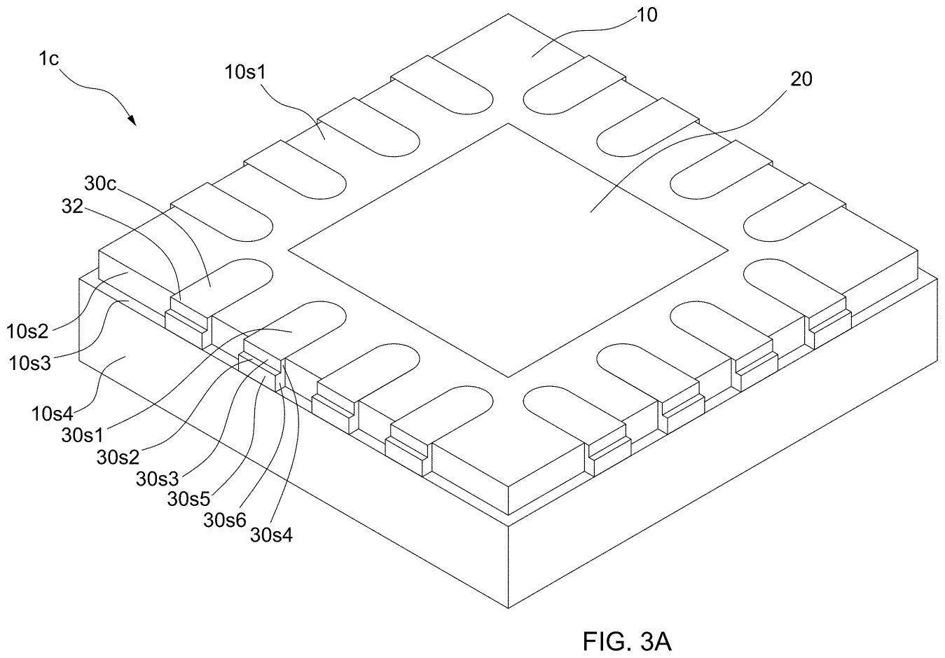

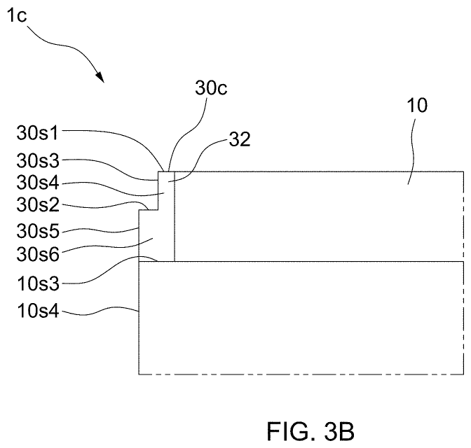

FIG. 3A illustrates a three-dimensional view of a semiconductor device package 1c according to some embodiments of the present disclosure. The semiconductor device package 1c of FIG. 3A has a similar structure to that of the semiconductor device package 1b of FIG. 2A, except for the lead 30c of the semiconductor device package 1c.

In some embodiments, the lead 30c may include a lateral surface 30s5. The upper surface 30s2 may extend between the lateral surface 30s5 and the lateral surface 30s3. The lateral surface 30s5 of the lead 30c may be exposed from the lateral surface 10s4 of the encapsulant 10. The lateral surface 30s5 of the lead 30c may be substantially coplanar with the lateral surface 10s4 of the encapsulant 10. In some embodiments, the upper surface 30s2 of the lead 30c and the upper surface 10s3 and the upper surface 10s3 of the encapsulant 10 may be at different elevations. In some embodiments, the upper surface 30s2 of the lead 30c may be at an elevation higher than that of the upper surface 10s3 of the encapsulant 10. In some embodiments, the lead 30c may further include a lateral surface 30s6. The lateral surface 30s6 may extend from the lateral surface 30s5 of the lead 30c toward the lateral surface 10s2 of the encapsulant 10. The lateral surface 30s6 may extend from the upper surface 30s2 of the lead 30c toward the upper surface 10s3 of the encapsulant 10. In some embodiments, the lateral surface 30s6 of the lead 30c may be substantially coplanar with and in contact with the lateral surface 30s4 of the lead 30c.

FIG. 3B illustrates a partial side view of the semiconductor device package 1c of FIG. 3A. As shown in FIG. 3B, the protruding portion 32 of the lead 30c may have an L-shape, which is defined by the lateral surface 30s4 and the lateral surface 30s6. In some embodiments, the protruding portion 32 of the lead 30c may have a step-like structure, which may include a first step defined by the upper surface 30s1 and the lateral surface 30s3, and a second step defined by the upper surface 30s2 and the lateral surface 30s5. In some embodiments, the protruding portion 32 of the lead 30c may extend to the lateral surface 10s4 of the encapsulant 10. As compared to the embodiments illustrated in FIG. 1, the protruding portion 32 of the lead 30c may provide a greater area for jointing a conductive layer, for example, a solder, thereby increasing the rigidity of the semiconductor device package 1c. Further, the formation of the protruding portion 32 may assist in inspecting solder joints more easily by automated optical inspection (AOI).

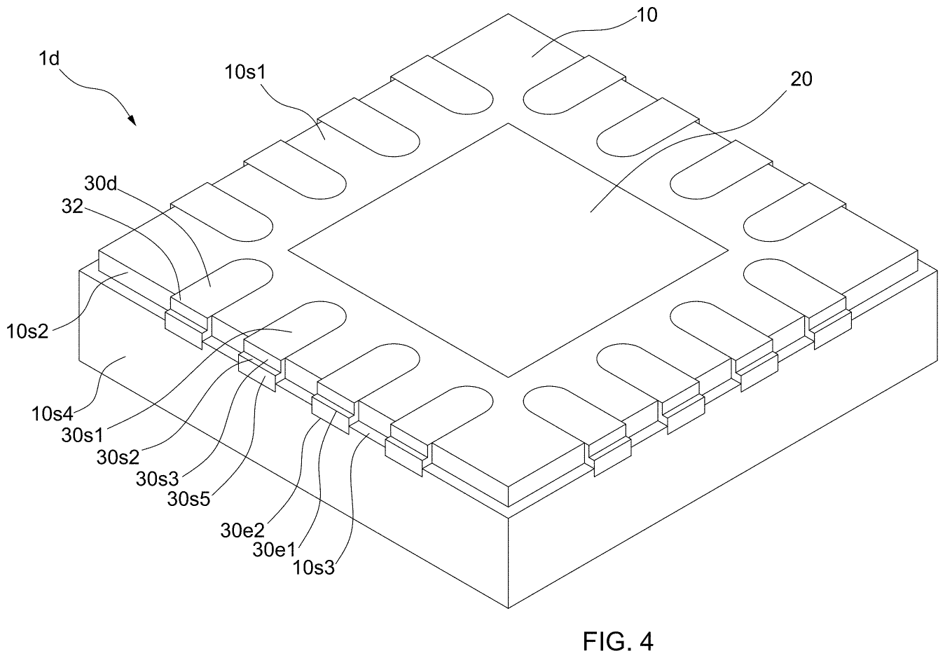

FIG. 4 illustrates a three-dimensional view of a semiconductor device package 1d according to some embodiments of the present disclosure. The semiconductor device package 1d of FIG. 4 has a similar structure to that of the semiconductor device package 1c of FIG. 3A, except for the lead 30d of the semiconductor device package 1d.

The lateral surface 30s5 of the lead 30d may have an edge 30e1 and an edge 30e2. The edge 30e1 may be at an elevation higher than that of the edge 30e2. The edge 30e1 of the lateral surface 30s5 may be at substantially the same elevation as that of the upper surface 30s2. In some embodiments, the upper surface 10s3 of the encapsulant 10 may be at an elevation between the edge 30e1 and the edge 30e2. .

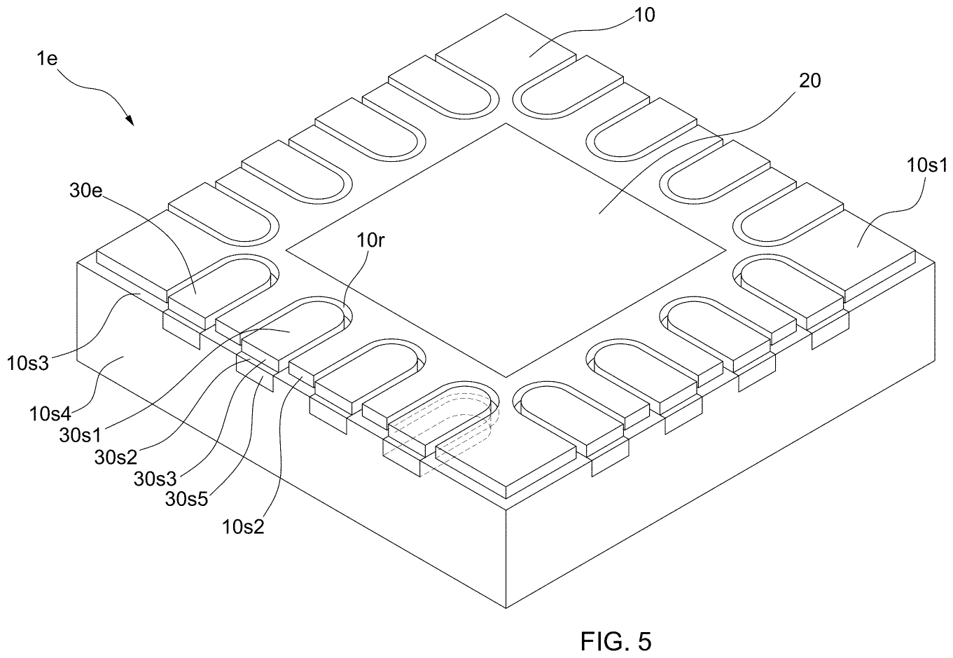

FIG. 5 illustrates a three-dimensional view of a semiconductor device package 1e according to some embodiments of the present disclosure. The semiconductor device package 1e of FIG. 5 has a similar structure to that of the semiconductor device package 1b of FIG. 2A, except for the gaps 10r.

In some embodiments, the encapsulant 10 may define a plurality of gaps 10r. The gap 10r may be recessed from the upper surface 10s1 of the encapsulant 10 and/or the lateral surface 10s2 of the encapsulant 10. The gap 10r may be around one lead 30e. In some embodiments, the gap 10r may surround one lead 30e. The gap 10r may be located between the encapsulant 10 and the lead 30e. The dotted line shown in FIG. 5 is used to present the profile of the lead 30e behind the encapsulant 10 in this three-dimensional view. In some embodiments, the upper surface 30s1 of the lead 30e may be spaced apart (or partially spaced apart) from the upper surface 10s1 of the encapsulant 10 by a gap 10r. In some embodiments, the protruding portion 32 of the lead 30e may be separated from the lateral surface 10s2 of the encapsulant 10 by a gap 10r. In some embodiments, the protruding portion 32 of the lead 30e may be separated (or partially separated) from the upper surface 10s1 of the encapsulant 10 by a gap 10r. In some embodiments, a depth of the gap 10r may be less than or substantially the same as a distance from the upper surface 10s1 of the encapsulant 10 to the upper surface 10s3 of the encapsulant 10. In some embodiments, the lateral surface of the lead 30e, extending between the upper surface 30s1 of the lead 30e and the upper surface 10s3 of the encapsulant, may be exposed from the gap 10r. In this embodiment, the gap 10r may be used to, for example, accommodate more solder materials, and therefore, it may enhance the jointing strength and prevents a short caused by excessive solder materials electrically connecting two adjacent leads 30e. Further, the protruding portion 32 may provide a greater area for jointing a conductive layer, for example, a solder, thereby increasing the rigidity of the semiconductor device package 1e.

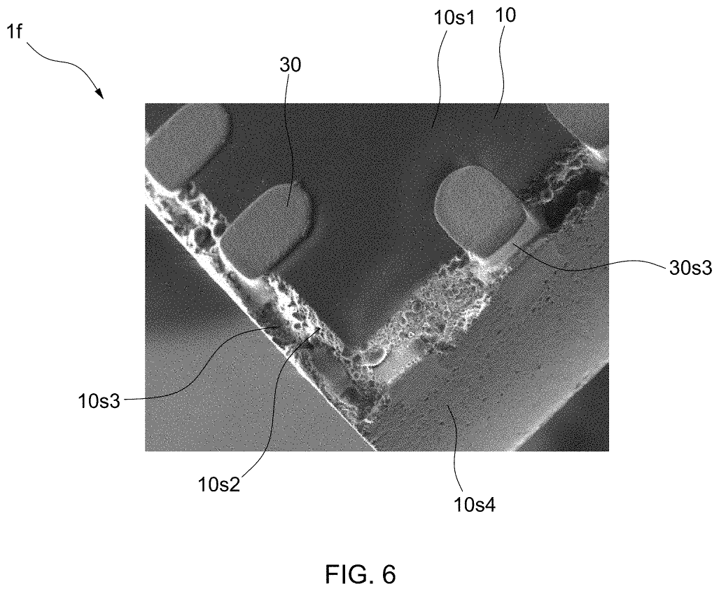

FIG. 6 illustrates a scanning electron microscopic image of a semiconductor device package if according to some embodiments of the present disclosure.

In some embodiments, the lateral surface 10s2 of the encapsulant 10 is a rough surface. In some embodiments, the roughness of the lateral surface 10s2 of the encapsulant 10 may be greater than that of the lateral surface 10s4 of the encapsulant 10. In some embodiments, the roughness of the lateral surface 10s2 of the encapsulant 10 may be greater than that of the upper surface 10s1 of the encapsulant 10. In some embodiments, the upper surface 10s3 of the encapsulant 10 is a rough surface. The roughness of the upper surface 10s3 of the encapsulant 10 may be greater than that of the lateral surface 10s4 of the encapsulant 10. The roughness of the upper surface 10s3 may be greater than that of the upper surface 10s1 of the encapsulant 10. In this embodiment, the lateral surface 10s2 and the lateral surface 10s4 of the encapsulant 10 are generated by two different techniques, resulting in different roughnesses of cut surfaces. Further, no burr defects or less burr defects are formed on the lateral surface 30s3 of the lead 30, which may advance mass production of the semiconductor device packages and reduce short defect.

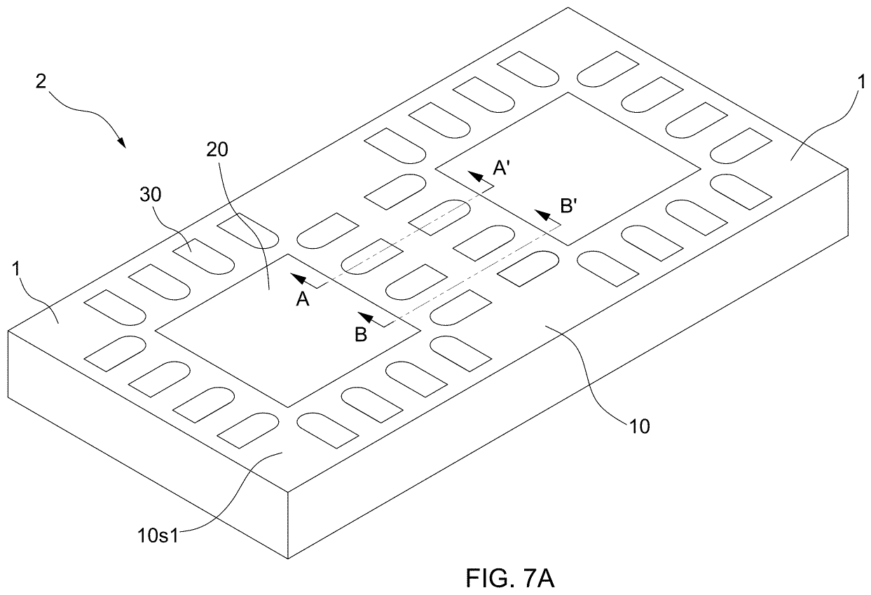

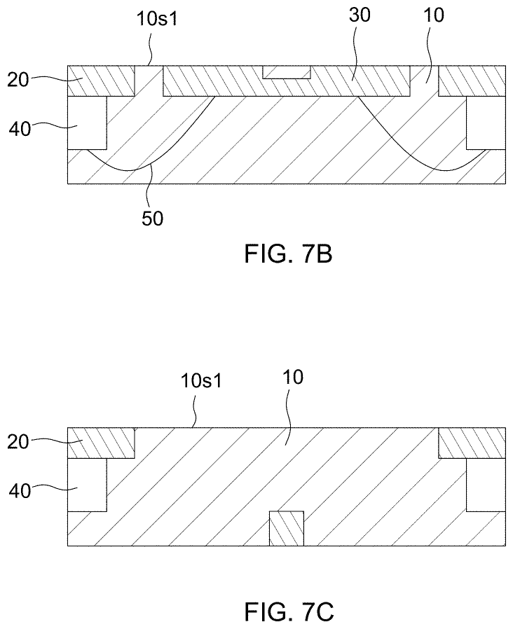

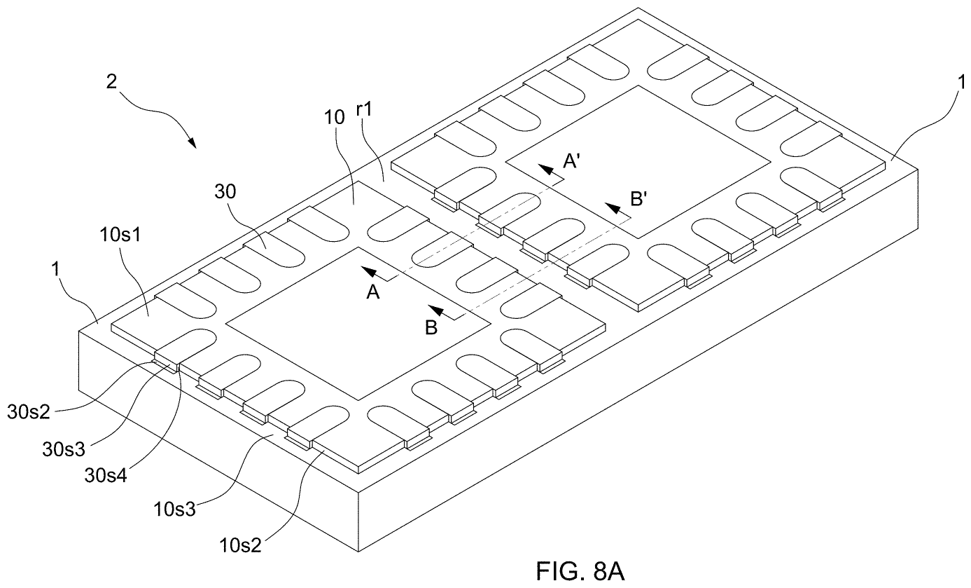

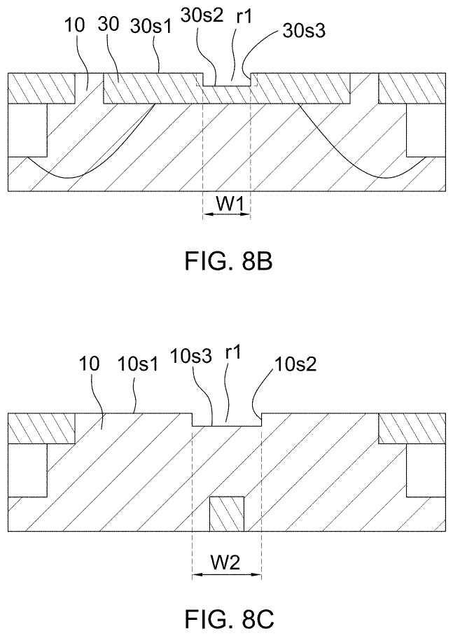

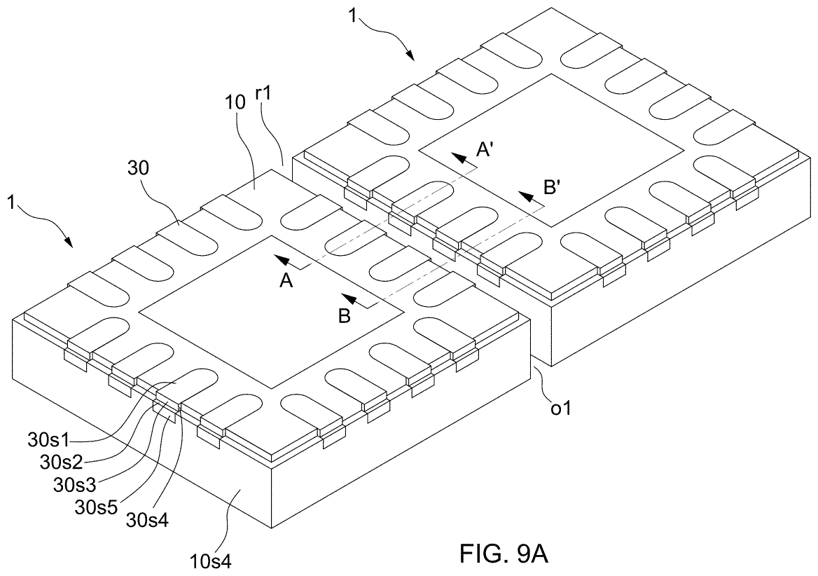

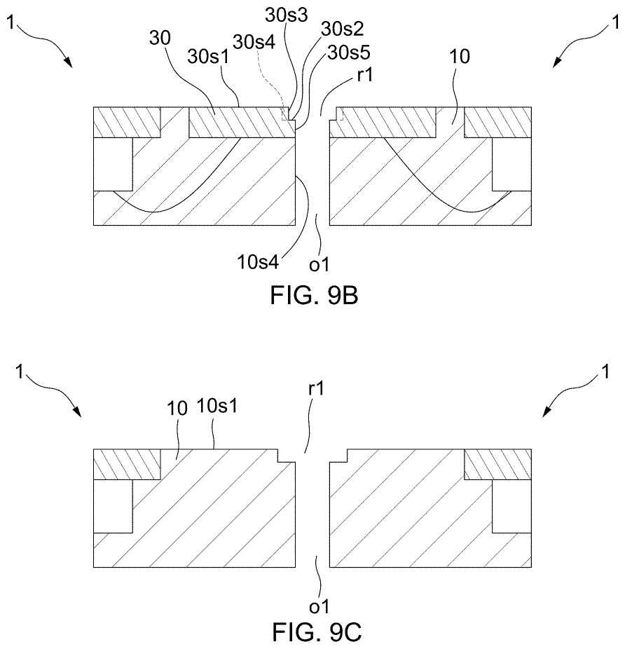

FIG. 7A, FIG. 7B, FIG. 7C, FIG. 8A, FIG. 8B, FIG. 8C, FIG. 9A, FIG. 9B and FIG. 9C illustrate various stages of another method for manufacturing a semiconductor device package in accordance with some embodiments of the present disclosure, wherein FIG. 7A, FIG. 8A and FIG. 9A are three-dimensional views, FIG.7B, FIG. 8B and FIG. 9B are cross-sectional views along line A-A′ of FIG. 7A, FIG. 8A and FIG. 9A, respectively, and FIG. 7C, FIG. 8C and FIG. 9C are cross-sectional views along line B-B′ of FIG. 7A, FIG. 8A and FIG. 9A, respectively.

Referring to FIG. 7A, FIG. 7B and FIG. 7C, a package structure 2 is provided. The package structure 2 may include two or more semiconductor device package units 1 that are not separated yet. Each of the semiconductor device package units 1 may include an encapsulant 10, a die paddle 20 and a plurality of leads 30. The plurality of leads 30 are disclosed or located around a peripheral edge of the semiconductor device package unit 1 and exposed from an upper surface 10s1 of the encapsulant 10 of the package structure 2.

As shown in FIG. 7B, the semiconductor device package unit 1 may include a semiconductor device 40 and a plurality of wire bonds 50. The semiconductor device 40 may be disposed on the die paddle 20. The semiconductor device 40 may include integrated circuits (ICs). The wire bond 50 may be disposed on the semiconductor device 40. The wire bond 50 may be configured to electrically connect the semiconductor device 40 and the lead 30. The wire bond 50 may include or be made of metal materials, such as copper (Cu), silver (Ag), aluminum (Al), gold (Au), or an alloy thereof. The encapsulant 10 may cover the semiconductor device 40 and the wire bond 50.

Referring to FIG. 8A, FIG. 8B and FIG. 8C, an energy-beam ablation operation may be performed to half-cut the package structure 2 from the upper surface 10s1 of the encapsulant 10 to form a recess rl. The recess r1 may locate between two adjacent semiconductor device package units 1. The recess r1 may surround a periphery of each of the semiconductor device package units 1. In such operation, a portion of the upper surface 10s1 is irradiated and removed by an energy-beam to form the recess rl. The energy-beam may be a laser beam, for example, an ultraviolet (UV) laser beam, which may have a wavelength of about 200 nm, but is not limited thereto. The species and intensity of the energy-beam may be selected, depending on the materials of the encapsulant and the leads, so that the energy-beam can remove the targeted material(s). In some embodiments, the energy-beam can remove a portion of the encapsulant 10 with no or less damage to the leads 30. In some embodiments, the energy-beam can remove a portion of the encapsulant 10 and the leads 30. The energy-beam ablation operation may remove the encapsulant 10 from a periphery of each of the semiconductor device package units 1. After the energy-beam ablation operation is performed, the lateral surface 10s2 and the upper surface 10s3 of the encapsulant 10 are exposed from the recess rl. Further, the upper surface 30s2 and the lateral surface 30s3 of the lead 30 are exposed from the recess rl.

The energy-beam ablation operation may have different selectivity on the encapsulant 10 and the lead 30. For example, the encapsulant 10 may be removed faster than the lead 30, causing the recess r1 to have different widths along line A-A′ and line B-B′. As shown in FIG. 8B and FIG. 8C, the recess r1 may have a width W1 and a width W2 greater than the width W1 where the width W1 may be defined as a distance between two lateral surfaces 30s3 of the leads 30 of adjacent semiconductor device package units 1, and the width W2 may be defined as a distance between two lateral surfaces 10s2 of the encapsulant 10 of adjacent semiconductor device package units 1. As a result, the lead 30 may protrude from the lateral surface 10s2 of the encapsulant 10. After the energy-beam ablation operation is performed, the lead 30 may have three lateral surfaces (e.g., one lateral surface 30s3 and two lateral surfaces 30s4) exposed from the recess r1. The lateral surface 30s3 of the lead 30 and the lateral surface 10s2 of the encapsulant 10 may not be coplanar. Further, the surfaces of the encapsulant 10 formed by the energy-beam ablation operation may have a greater roughness. Therefore, the lateral surface 10s2 and the upper surface 10s3 of the encapsulant 10 may be rough surfaces as shown in FIG. 6.

In another embodiment, the energy-beam ablation operation may be used to form the gap (e.g., the gap 10r shown in FIG. 5) recessed from the sidewall of the recess r1 and surrounding the lead 30. In this embodiment, the energy-beam ablation operation may have two steps: forming the recess r1 and forming the gap. In some embodiments, the recess r1 may be formed before the formation of the gap. In another embodiment, the gap may be formed before the formation of the recess r1. The sequence of forming the recess r1 and the gap is not intended to be limited.

In another embodiment, the energy-beam ablation operation may remove more encapsulant 10 such that the recess 10r may have a greater depth. In this embodiment, the lateral surface (such as the lateral surface 30s6 shown in FIG. 3A) of the lead 30 may be exposed from the recess r1.

Referring to FIG. 9A, FIG. 9B and FIG. 9C, a singulation operation may be performed to form an opening ol from the recess r1 to separate the semiconductor device package units 1. In some embodiments, the singulation operation may remove a portion of the encapsulant 10 and the lead 30. In some embodiments, the singulation operation may use a saw cutting the encapsulant 10 and the lead 30. After the singulation operation is performed, the lateral surface 10s4 of the encapsulant 10 may be formed, and the lateral surface 30s5 of the lead 30 may be exposed from the lateral surface 10s4 of the encapsulant 10. A width (or an aperture) of the recess r1 is greater than a width (or an aperture) of the opening o1. In some embodiments, an electroplating process may be performed to form a conductive layer (e.g., solder, not shown) on the exposed surface (such as the upper surfaces 30s1 and 30s2 as well as the lateral surfaces 30s3 and 30s4) of the lead 30 before the singulation operation.

In a comparative example using a saw to perform two singulation operations, the lateral surface of the lead may have burr defects caused by the leads sticking on the saw, especially during the first singulation operation (i.e., the half-cut operation). In the embodiments of the present disclosure, an energy-beam ablation operation is used to replace the first singulation operation to half cut the package structure 2. Compared to the comparative example, no burr defects or less burr defects are formed on the lateral surface 30s3 of the lead 30. Further, in some further embodiments, the lead 30 may protrude from the encapsulant 10 to provide a greater area for jointing the conductive layer, enhancing the rigidity of the semiconductor device package 1.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the term “vertical” is used to refer to upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between the highest point and the lowest point of the surface is no greater than 5 μm, no greater than 2 μm, no greater than 1 μm, or no greater than 0.5μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor device package, comprising:
an encapsulant having a first upper surface, a second upper surface, a first lateral surface and a second lateral surface, wherein the first lateral surface extends between the first upper surface and the second upper surface, and the second upper surface extends between the first lateral surface and the second lateral surface; and
a plurality of leads embedded in the encapsulant, at least one of the plurality of leads having a first surface exposed from the first upper surface of the encapsulant, a second surface exposed from the second upper surface of the encapsulant and a third surface extending between the first surface and the second surface and a fourth surface extending from the third surface of the lead toward the first lateral surface of the encapsulant.

2. The semiconductor device package of claim 1, wherein the fourth surface of the lead is in contact with the first lateral surface of the encapsulant.

3. The semiconductor device package of claim 1, wherein a distance from the second lateral surface of the encapsulant to the first lateral surface of the encapsulant is greater than a distance from the third surface of the lead to the first lateral surface of the encapsulant.

4. The semiconductor device package of claim 1, wherein the lead has a fifth surface substantially coplanar with the second lateral surface of the encapsulant and a sixth surface extending from the fifth surface of the lead toward the first lateral surface of the encapsulant.

5. The semiconductor device package of claim 4, wherein the sixth surface of the lead is substantially coplanar with and in contact with the fourth surface of the lead.

6. The semiconductor device package of claim 1, wherein the second upper surface of the encapsulant is at a lower elevation than the second surface of the lead.

7. The semiconductor device package of claim 1, wherein the second upper surface of the encapsulant is at substantially the same elevation as the second surface of the lead.

8. The semiconductor device package of claim 1, wherein a roughness of the first lateral surface of the encapsulant is greater than that of the second lateral surface of the encapsulant or a roughness of the second upper surface of the encapsulant is greater than that of the second lateral surface of the encapsulant.

9. The semiconductor device package of claim 1, wherein the encapsulant defines a gap recessed from the first upper surface of the encapsulant, and the gap is located between the lead and the encapsulant.

10. The semiconductor package structure of claim 9, wherein a depth of the gap is less than or substantially the same as a distance from the first upper surface of the encapsulant to the second upper surface of the encapsulant.

11. A semiconductor device package, comprising:
an encapsulant having a first upper surface, a second upper surface and a first lateral surface extending between the first upper surface and the second upper surface; and
a plurality of leads embedded in the encapsulant, wherein at least one of the plurality of leads has a protruding portion protruding from the second upper surface of the encapsulant, the first lateral surface of the encapsulant or both.

12. The semiconductor device package of claim 11, wherein the encapsulant has a second lateral surface, and the second upper surface extends between the first lateral surface and the second lateral surface, and wherein the protruding portion of the lead is recessed from the second lateral surface of the encapsulant.

13. The semiconductor device package of claim 11, wherein the encapsulant has a second lateral surface, and the second upper surface extends between the first lateral surface and the second lateral surface, and wherein the protruding portion of the lead extends to the second lateral surface of the encapsulant.

14. The semiconductor device package of claim 11, wherein the protruding portion of the lead is in contact with the second upper surface and the first lateral surface of the encapsulant.

15. The semiconductor device package of claim 11, wherein a roughness of the first lateral surface of the encapsulant is greater than that of the first upper surface of the encapsulant or a roughness of the second upper surface of the encapsulant is greater than that of the first upper surface of the encapsulant.

16. The semiconductor device package of claim 11, wherein the protruding portion of the lead is separated from the first lateral surface of the encapsulant by a gap.

17. A method of manufacturing a semiconductor device package, comprising:
(a) providing a package structure comprising two or more semiconductor device package units and an encapsulant covering a semiconductor device of each of the semiconductor device package units, wherein each of the semiconductor device package units comprises a plurality of leads disposed around a peripheral edge of the semiconductor device package unit and exposed from an upper surface of the package structure;
(b) performing an energy-beam ablation operation to half-cut the package structure from the upper surface of the package structure to form a recess along the peripheral edge of the semiconductor device package unit, wherein a lateral surface of the leads is exposed from the recess; and
(c) performing a singulation operation to form an opening from the recess, wherein a width of the recess is greater than a width of the opening.

18. The method of claim 17, wherein the leads are protruding from a sidewall of the recess.

19. The method of claim 17, further comprising:
performing an electroplating process to form a conductive layer on the exposed surface of the leads before the singulation operation.

20. The method of claim 17, further comprising:
forming a gap recessed from a sidewall of the recess and around the lead.
